(19) United States
(12) Patent Application Publication
(10) Pub. No.: US 2006/0194441 A1
(43) Pub. Date: Aug. 31, 2006

(54) Method for etching a silicon wafer and method for performing differentiation between the obverse and the reverse of a silicon wafer using the same method

(76) Inventors: Sakae Koyata, Tokyo (JP); Kazushige Takaishi, Tokyo (JP); Masashi Norimoto, Tokyo (JP)

Correspondence Address: REED SMITH, LLP;ATTN: PATENT RECORDS DEPARTMENT, 599 LEXINGTON AVENUE, 29TH FLOOR, NEW YORK, NY, 10022-7650, US

(21) Appl. No.: 11/067,117

(22) Filed: Feb. 25, 2005

(51) Int. Cl. H01L 21/302; B44C 1/22; C23F 1/00

(52) U.S. Cl. 438/745; 216/83; 438/689; 438/692

(57) ABSTRACT

The invention is improvement of a silicon wafer etching method of storing an acid etching solution and an alkali etching solution respectively in plural etching tanks, and immersing a silicon wafer having a work-degenerated layer, which has experienced a lapping process and then a cleaning process, in the acid etching solution and the alkali etching solution in order. Its characteristic configuration is in that an alkali etching process is performed after an acid etching process, the etching removal depth for acid etching is made to be equal to or larger than the etching removal depth for alkali etching, and the etching rate of acid etching is made to be 0.0075 μm/sec to 0.05 μm/sec in total of the obverse and the reverse of the silicon wafer.

### BACKGROUND OF THE INVENTION

1. Field of the Invention

The present invention relates to improvement of a method for etching away a work-degenerated layer of a surface of a wafer, said work-degenerated layer being generated in a silicon wafer manufacturing process. More particularly, the present invention relates to a method for performing differentiation between the obverse and the reverse of a wafer by mirror-polishing only an etched surface of the wafer.

2. Prior Art

A process of manufacturing a semiconductor silicon wafer is generally composed of processes of chamfering, mechanically polishing (lapping), etching, mirror-polishing and cleaning a wafer obtained by cutting out and slicing a silicon single crystal ingot pulled, and thereby a wafer having a high-accuracy flatness is produced. In these processes, depending on purposes, some of them are replaced or repeated at plural times, or other processes such as heat treatment, grinding and the like are added or replaced, and thus various processes are performed.

A silicon wafer which has experienced machining processes such as block cutting, diameter grinding, slicing, lapping and the like has a damaged layer, namely, a work-degenerated layer on a surface of it. Since the work-degenerated layer causes crystal defects such as slip dislocation and the like, degrades the mechanical strength of a wafer or exerts a bad influence on the electric characteristics of it in a device manufacturing process, the work-degenerated layer must be completely removed.

An etching process is performed in order to remove the work-degenerated layer. The etching process includes an acid etching process using an acid etching solution of mixed acid and the like, and an alkali etching process using an alkali etching solution of NaOH and the like.

By performing an acid etching process, however, a flatness obtained by lapping is damaged and undulation of the order of millimeters or unevenness called peel appears on the etched surface. And there has been a problem that pits of several microns in local depth and of several microns to several ten microns in size (hereinafter, referred to as facets) are generated by performing an alkali etching process.

As a method for solving the above-mentioned problems, there have been proposed a wafer processing method of performing an alkali etching process and then performing an acid etching process under the condition that the etching removal depth for alkali etching is made larger than the etching removal depth for acid etching, and a wafer processed by this method (Japanese Patent Laid-Open Publication No. Hei 11-233,485).

By the above-described method, it is possible to manufacture a wafer having an etched surface which removes a work-degenerated layer as keeping the flatness obtained by lapping, improves the surface roughness, and particularly makes local facets shallower, has a smooth uneven shape and makes particles or contaminations difficult to appear.

On the other hand, since the detection of existence of a wafer is performed by means of the reverse face of the wafer in a carrying system of a device process, when the reverse face of a mirror-polished wafer is mirror-like, there have occurred problems such as difficult detection, erroneous detection and the like.

A wafer having a mirror-polished surface (hereinafter, referred to as PW: Polished Wafer) disclosed in Japanese Patent Laid-Open Publication No. Hei 11-233,485 described above has a problem of being not capable of providing a wafer which has a good flatness as desired by a device manufacturer and has a small reverse face roughness of PW.

An object of the present invention is to provide a silicon wafer etching method for providing a good flatness and making a reverse face roughness small in a wafer having a mirror-polished surface.

Another object of the present invention is to provide a method of performing differentiation between the obverse and the reverse of a silicon wafer which has both faces each having a high-accuracy flatness and a small surface roughness and makes it possible to visually identify the obverse and reverse faces of the wafer.

### SUMMARY OF THE INVENTION

The invention according to claim 1 is improvement of a silicon wafer etching method of storing an acid etching solution and an alkali etching solution respectively in plural etching tanks, and immersing a silicon wafer having a work-degenerated layer, which has experienced a lapping process and then a cleaning process, in the acid etching solution and the alkali etching solution in order.

Its characteristic configuration is in that an alkali etching process is performed after an acid etching process, the etching removal depth for acid etching is equal to or larger than the etching removal depth for alkali etching, and the etching rate of acid etching is made to be 0.0075 μm/sec to 0.05 μm/sec in total of the obverse and the reverse of the silicon wafer.

In the invention according to claim 1, an alkali etching process is performed after an acid etching process, the etching removal depth for acid etching is made to be equal to or larger than the etching removal depth for alkali etching, and the etching rate of acid etching is made to be 0.0075 μm/sec to 0.05 μm/sec in total of the obverse and the reverse of the silicon wafer. A wafer etching-processed by immersing the wafer in an acid etching solution and an alkali etching solution in order under an etching condition prescribed in such a way can keep the flatness obtained by a lapping process and make the reverse face roughness small.

The invention according to claim 2 is an etching method according to claim 1, wherein the total etching removal depth for acid etching is made to be 10 to 20 μm in total of the obverse and the reverse of a silicon wafer, the total etching removal depth for alkali etching is made to be 5 to 10 μm in total of the obverse and the reverse of the silicon wafer, and the total etching removal depth for acid etching and alkali etching is made to be 20 to 25 μm in total of the obverse and the reverse of the silicon wafer.

The invention according to claim 3 is an etching method according to claim 1, wherein the number of acid etching tanks is one to three and the number of alkali etching tanks is one to three.

The invention according to claim 4 is an etching method according to claim 1, wherein the acid etching solution includes hydrofluoric acid and nitric acid.

The invention according to claim 5 is an etching method according to claim 4, wherein the acid etching solution further includes at least one of acetic acid, sulfuric acid and phosphoric acid.

The invention according to claim 6 is an etching method according to claim 1, wherein the alkali etching solution includes sodium hydroxide or potassium hydroxide.

The invention according to claim 7 is an etching method according to claim 6, wherein the alkali etching solution further includes lithium hydroxide.

The invention according to claim 8 is a method for performing differentiation between the obverse and the reverse faces of a wafer by mirror-polishing only the obverse face of the wafer etched by the method according to claim 1.

The invention according to claim 8 mirror-polishes only the obverse face of a wafer providing a good flatness by etching and being made small in reverse face roughness, and thereby makes it possible to visually identify the obverse and reverse faces of the wafer, said faces each having a high-accuracy flatness and a small surface roughness and said wafer having the obverse face having the degree of gloss desired by a device manufacturer.

### DETAILED DESCRIPTION OF THE PREFERRED EMBODIMENT

Next, an embodiment of the present invention is described.

A method for etching a silicon wafer according to the present invention is improvement of a silicon wafer etching method of storing an acid etching solution and an alkali etching solution respectively in plural etching tanks, and immersing a silicon wafer having a work-degenerated layer, which has experienced a lapping process and then a cleaning process, in the acid etching solution and the alkali etching solution in order, and its characteristic configuration is in that an alkali etching process is performed after an acid etching process, the etching removal depth for acid etching is made to be equal to or larger than the etching removal depth for alkali etching, and the etching rate of acid etching is made to be 0.0075 μm/sec to 0.05 μm/sec in total of the obverse and the reverse of the silicon wafer.

When the etching removal depth for acid etching is smaller than the etching removal depth for alkali etching, a disadvantage that the Ra surface roughness is deteriorated occurs. The reason is thought that a pit size is made larger due to the characteristic of alkali etching. Since the etching rate of acid etching being less than 0.0075 μm/sec in total of the obverse and the reverse of a wafer needs a too long time for etching, it is not practical. When the etching rate exceeds 0.05 μm/sec, there occurs a disadvantage that the flatness of a wafer is deteriorated or the undulation of the order of several millimeters called nano-topography is made larger. The etching rate is preferably 0.03 to 0.04 μm/sec.

Hereupon, the degree of gloss is defined in Japanese Industrial Standard (JIS Z 8741). According to this Standard, the degree of gloss is represented as a numeric value representing in percents the ratio of the mirror-reflected luminous flux Ts of light incident on a sample surface at an incidence angle θ to the mirror-reflected luminous flux Ψ_{S0} of light incident on a glass surface of 1.567 in refractive index in the same measurement system. The degree of gloss Gr (θ) can be represented by the following formula (1), and an incidence angle θ in case of measuring the degree of gloss of the surface of a silicon wafer is 60°.
Gloss Gr(θ)=Ψ_{S}/Ψ_{S0}×100 (1)

The etching mechanism of acid etching consists of the oxidation of silicon by an oxidizing species contained in nitric acid and the like or another compound, and the removal of oxide by hydrofluoric acid and the like or another reducing compound. Acetic acid, sulfuric acid, phosphoric acid, water or the like is added as a diluent in order to control the etching rate of acid etching. Additive solutions to be used as these diluents have another effect of varying the surface tension and viscosity of an acid etching solution, and are selected according to the purposes of them. The etching rate of acid etching solution is reduced by adding a diluent. The surface roughness trends to become larger with the reduction of the etching rate. Accordingly, there appears an effect that Ra being an index of surface roughness becomes larger and the degree of gloss is made smaller.

By reason that the in-surface uniformity of a wafer is improved with regard to the heat generated with an etching reaction, the flatness trends to become better as the etching rate becomes smaller.

A silicon wafer is etched so that the total etching removal depth for acid etching is made to be 10 to 20 μm in total of the obverse and the reverse of the silicon wafer, the total etching removal depth for alkali etching is made to be 5 to 10 μm in total of the obverse and the reverse of the silicon wafer, and the total etching removal depth for acid etching and alkali etching is made to be 20 to 25 μm in total of the obverse and the reverse of the silicon wafer. When the total etching removal depth for acid etching is less than the lower limit, there occur disadvantages of resulting in a large surface roughness, being unable to accurately control the etching removal depth and the like, and when it exceeds the upper limit, there occurs a disadvantage that undulation of the order of several millimeters called nano-topography becomes larger. When the total etching removal depth for alkali etching is less than the lower limit, the degree of gloss does not reach a desired numeric value, and when it exceeds the upper limit, there occurs a disadvantage that nano-topography appears. When the total etching removal depth for acid etching and alkali etching is less than the lower limit, a work strain is not sufficiently removed and a work defect caused by crack and the like may occur in a subsequent process. Further, this may lead to deterioration in device characteristics, defective devices and the like. When the total etching removal depth for acid etching and alkali etching exceeds the upper limit, there occur disadvantages of being deteriorated in flatness, being made larger in nano-topography, being worsened in Ra surface roughness, being larger in pit size due to the characteristic of alkali etching, and the like.

The number of etching tanks of the present invention is two to six. Combinations of acid etching tanks and alkali etching tanks are shown in table 1.

TABLE 1

| Number of | Combinations of acid etching |
|---|---|
| etching tanks | tanks and alkali etching tanks |
| 2 tanks | Acid-Alkali |
| 3 tanks | Acid-Acid-Alkali |
| | Acid-Alkali-Acid |
| | Acid-Alkali-Alkali |
| 4 tanks | Acid-Acid-Acid-Alkali |
| | Acid-Acid-Alkali-Acid |
| | Acid-Acid-Alkali-Alkali |
| | Acid-Alkali-Acid-Acid |
| | Acid-Alkali-Acid-Alkali |
| | Acid-Alkali-Alkali-Acid |
| | Acid-Alkali-Alkali-Alkali |
| 5 tanks | Acid-Acid-Acid-Alkali-Alkali |
| | Acid-Acid-Alkali-Acid-Alkali |
| | Acid-Acid-Alkali-Alkali-Acid |
| | Acid-Acid-Alkali-Alkali-Alkali |
| | Acid-Alkali-Acid-Acid-Alkali |
| | Acid-Alkali-Acid-Alkali-Acid |
| | Acid-Alkali-Acid-Alkali-Alkali |
| | Acid-Alkali-Alkali-Acid-Acid |
| | Acid-Alkali-Alkali-Acid-Alkali |
| | Acid-Alkali-Alkali-Alkali-Acid |
| 6 tanks | Acid-Acid-Acid-Alkali-Alkali-Alkali |
| | Acid-Acid-Alkali-Acid-Alkali-Alkali |
| | Acid-Acid-Alkali-Alkali-Acid-Alkali |
| | Acid-Acid-Alkali-Alkali-Alkali-Acid |
| | Acid-Alkali-Acid-Acid-Alkali-Alkali |
| | Acid-Alkali-Acid-Alkali-Acid-Alkali |
| | Acid-Alkali-Acid-Alkali-Alkali-Acid |
| | Acid-Alkali-Alkali-Acid-Acid-Alkali |
| | Acid-Alkali-Alkali-Acid-Alkali-Acid |
| | Acid-Alkali-Alkali-Alkali-Acid-Acid |

When the number of etching tanks exceeds the upper limit, the surface roughness of a wafer is made worse. Preferably the number of etching tanks is two to four, and in the optimal aspect in this case, the number of acid etching tanks is one to two and the number of alkali etching tanks is two or less.

For example, in case of two etching tanks, a wafer is immersed in etching tanks in order of an acid etching tank and an alkali etching tank. And in case of three etching tanks, a wafer is immersed in etching tanks in order of an acid etching tank, an alkali etching tank and an alkali etching tank, or in order of an acid etching tank, an acid etching tank and an alkali etching tank, or in order of an acid etching tank, an alkali etching tank and an acid etching tank.

And a rinsing process needs to be performed between the respective etching processes. Since acid and alkali attached to a wafer are washed away by performing a rinsing process between etching processes, in a subsequent process it is possible to prevent a chemical liquid from being carried in from an etching tank in the previous process and minimize the fluctuation in composition of a chemical liquid.

An acid etching solution comprises hydrofluoric acid and nitric acid, and may further comprise at least one of acetic acid, sulfuric acid and phosphoric acid. And an alkali etching solution uses a solution containing sodium hydroxide or potassium hydroxide, and may be a high-concentration solution obtained by dissolving pellets or powder of high-purity KOH, NaOH or the like. And it may further comprise lithium hydroxide.

Since the obverse face of a silicon wafer obtained by mirror-polishing only the obverse face of the silicon wafer, said obverse face being etched by an etching method of the present invention, has a higher degree of gloss than the reverse face of it, it is possible to perform differentiation between the obverse and the reverse of the wafer to a visually identifiable degree.

As described above, according to the present invention, there is provided improvement of a silicon wafer etching method of storing an acid etching solution and an alkali etching solution respectively in plural etching tanks, and immersing a silicon wafer having a work-degenerated layer, which has experienced a lapping process and then a cleaning process, in the acid etching solution and the alkali etching solution in order. This is in that an alkali etching process is performed after an acid etching process, the etching removal depth for acid etching is made to be equal to or larger than the etching removal depth for alkali etching, and the etching rate of acid etching is made to be 0.0075 μm/sec to 0.05 μm/sec in total of the obverse and the reverse of the silicon wafer. The reverse face flatness, the degree of gloss and the surface roughness desired by a device manufacturer can be obtained by prescribing acid and alkali etching processes in the above-described condition.

Due to this, by performing a mirror-polishing process being a subsequent process on only the obverse face of a wafer obtained by this etching, the obverse face of the wafer is made higher in degree of gloss than the reverse face of it, both faces of the wafer each have a high-accuracy flatness and a small surface roughness, and thereby it is possible to perform differentiation between the obverse and the reverse of the wafer to a visually identifiable degree without problems such as difficult detection, erroneous detection and the like in detection of existence of the wafer in a carrying system of a device process.

What is claimed is:

1. A silicon wafer etching method of storing an acid etching solution and an alkali etching solution respectively in plural etching tanks, and immersing a silicon wafer having a work-degenerated layer, which has experienced a lapping process and then a cleaning process, in the acid etching solution and the alkali etching solution in order, wherein;
an alkali etching process is performed after an acid etching process, the etching removal depth for said acid etching is made to be equal to or larger than the etching removal depth for said alkali etching, and
the etching rate of said acid etching is made to be 0.00751 μm/sec to 0.05 μm/sec in total of the obverse and the reverse of the silicon wafer.

2. The etching method according to claim 1, wherein the etching removal depth for acid etching is made to be 10 to 20 μm in total of the obverse and the reverse of the silicon wafer, the etching removal depth for alkali etching is made to be 5 to 10 μm in total of the obverse and the reverse of the silicon wafer, and the total etching removal depth for the acid etching and the alkali etching is made to be 20 to 25 μm in total of the obverse and the reverse of the silicon wafer.

3. The etching method according to claim 1, wherein the number of acid etching tanks is one to three and the number of alkali etching tanks is one to three.

4. The etching method according to claim 1, wherein the acid etching solution includes hydrofluoric acid and nitric acid.

5. The etching method according to claim 4, wherein the acid etching solution further includes at least one of acetic acid, sulfuric acid and phosphoric acid.

6. The etching method according to claim 1, wherein the alkali etching solution includes sodium hydroxide or potassium hydroxide.

7. The etching method according to claim 6, wherein the alkali etching solution further includes lithium hydroxide.

8. A method for performing differentiation between the obverse and the reverse of a silicon wafer by mirror-polishing only the obverse face of the silicon wafer etched by the method according to claim 1.
